(19) United States
(12) Patent Application Publication
(10) Pub. No.: US 2025/0183857 A1
(43) Pub. Date: Jun. 5, 2025

(54) AMPLIFYING CIRCUIT

(71) Applicant: SUMITOMO ELECTRIC INDUSTRIES, LTD., Osaka-shi (JP)

(72) Inventor: Hirotaka ASAMI, Osaka-shi (JP)

(73) Assignee: SUMITOMO ELECTRIC INDUSTRIES, LTD., Osaka-shi (JP)

(21) Appl. No.: 18/935,094

(22) Filed: Nov. 1, 2024

(30) Foreign Application Priority Data
Dec. 1, 2023 (JP) 2023-204065

(51) Int. Cl. H03F 1/42; H03F 3/19

(52) U.S. Cl. CPC H03F 1/42; H03F 3/19; H03F 2200/36

(57) ABSTRACT

An amplifying circuit includes a divider that divides an input signal into a first signal and a second signal, a first amplifier that outputs a third signal to a first node, a second amplifier that outputs a fourth signal to a second node, a first inductor that connects the first node to the second node, a second inductor that connects the first node to a third node, a third inductor that connects the third node to a fourth node outputting an output signal obtained by combining the fourth signal and the third signal, a fourth inductor that connects the second node to the fourth node, a first capacitor shunt-connected to the third node, and a second capacitor shunt-connected to the fourth node, wherein an inductance of each of the first and the third inductors is larger than an inductance of each of the second and the fourth inductors.

### CROSS REFERENCE TO RELATED APPLICATIONS

This application claims priority based on Japanese Patent Application No. 2023-204065 filed on Dec. 1, 2023, and the entire contents of the Japanese patent application are incorporated herein by reference.

### TECHNICAL FIELD

The present invention relates to an amplifying circuit.

### BACKGROUND

A balanced amplifier is known as an amplifier circuit for amplifying a high frequency signal such as a microwave (see patent literature: Japanese National Publication of International Patent Application No. 2022-506367).

### SUMMARY

An amplifying circuit according to an embodiment of the present disclosure includes a divider that divides an input signal into a first signal and a second signal having a phase delayed from a phase of the first signal by 90 degrees, a first amplifier that amplifies the first signal and outputs the amplified first signal to a first node as a third signal, a second amplifier that amplifies the second signal and outputs the amplified second signal to a second node as a fourth signal, a first inductor that connects the first node to the second node, a second inductor that connects the first node to a third node, a third inductor that connect the third node to a fourth node, the fourth node outputting an output signal obtained by combining the fourth signal and the third signal, the third signal having a phase delayed from a phase of the fourth signal by 90 degrees, a fourth inductor that connects the second node to the fourth node, a first capacitor shunt-connected to the third node, and a second capacitor shunt-connected to the fourth node. An inductance of each of the first inductor and the third inductor is larger than an inductance of each of the second inductor and the fourth inductor.

### BRIEF DESCRIPTION OF THE DRAWINGS

FIG. 1 is a circuit diagram of an amplifying circuit according to a first embodiment.

FIG. 2 is a circuit diagram of a lumped-constant type branch-line coupler.

FIG. 3 is a circuit diagram of a distributed-constant type branch-line coupler.

FIG. 4 is a circuit diagram of an amplifying circuit according to a first comparative example.

FIG. 5 is a plan view illustrating a first implementation example of a combiner and an amplifier in the first embodiment.

FIG. 6 is a plan view illustrating a second implementation example of a combiner and an amplifier in the first embodiment.

FIG. 7 is a circuit diagram of an amplifying circuit according to a second embodiment.

FIG. 8 is a plan view illustrating an implementation example of a combiner and an amplifier in the second embodiment.

FIG. 9 is a circuit diagram of an amplifying circuit according to a third embodiment.

FIG. 10 is a plan view illustrating an implementation example of a combiner and an amplifier in the third embodiment.

FIG. 11 is a circuit diagram of an amplifying circuit according to a fourth embodiment.

### DETAILED DESCRIPTION

In the patent literature 1, a loss occurs due to a line connecting an amplifier and a coupler. In addition, the band is narrowed due to a ground capacitance at output terminals of amplifiers 4 and 5.

The present disclosure has been made in view of the above problems, and an object of the present disclosure is to reduce deterioration of characteristics.

### [Description of Embodiments of Present Disclosure]

First, the contents of embodiments of the present disclosure are listed and explained.

(1) An amplifying circuit according to an embodiment of the present disclosure includes a divider that divides an input signal into a first signal and a second signal having a phase delayed from a phase of the first signal by 90 degrees, a first amplifier that amplifies the first signal and outputs the amplified first signal to a first node as a third signal, a second amplifier that amplifies the second signal and outputs the amplified second signal to a second node as a fourth signal, a first inductor that connects the first node to the second node, a second inductor that connects the first node to a third node, a third inductor that connects the third node to a fourth node, the fourth node outputting an output signal obtained by combining the fourth signal and the third signal, the third signal having a phase delayed from a phase of the fourth signal by 90 degrees, a fourth inductor that connects the second node to the fourth node, a first capacitor shunt-connected to the third node, and a second capacitor shunt-connected to the fourth node. An inductance of each of the first inductor and the third inductor is larger than an inductance of each of the second inductor and the fourth inductor. This can reduce deterioration of characteristics.

(2) In the above (1), the inductance of each of the first inductor and the third inductor may be 0.8×√2 to 1.2×√2 of the inductance of each of the second inductor and the fourth inductor. Thus, the first to fourth inductors and the first and second capacitors can function as a branch-line coupler.

(3) In the above (1) or (2), no reactance element may be shunt-connected to each of the first node and the second node. Thus, the first to fourth inductors and the first and second capacitors can function as the branch-line coupler.

(4) In the above (3), when a center frequency of an operating band is denoted by fo, and a reference impedance is denoted by Zo, a capacitance C0 may be 0.8 times to 1.2 times 1/(2πfo×Zo)+1/(2πfo×Zo/√2), the capacitance C0 being a first ground capacitance of an output node of the first amplifier, a second ground capacitance of an output node of the second amplifier, and a capacitance of the first capacitor and the second capacitor, the inductance of each of the first inductor and the third inductor may be 0.8 times to 1.2 times Zo/(2πfo), and the inductance of each of the second inductor and the fourth inductor may be 0.8 times to 1.2 times Zo/(√2× (2πfo)). Thus, the amplifying circuit can function as a balanced amplifier.

(5) The amplifying circuit according to the above (1) or (2) may include a first reactance element shunt-connected to the first node, and a second reactance element shunt-connected to the second node. Thus, the first to fourth inductors, the first and second capacitors, and the first and second reactance elements can function as the branch-line coupler.

(6) In the above (5), when a center frequency of an operating band is denoted by fo, and a reference impedance is denoted by Zo, a capacitance C0 may be 0.8 times to 1.2 times 1/(2πfo×Zo)+1/(2πfo×Zo/√2), the capacitance C0 being a capacitance component obtained by combining a first ground capacitance of an output node of the first amplifier and the first reactance element, a capacitance component obtained by combining a second ground capacitance of an output node of the second amplifier and the second reactance element, and a capacitance of the first capacitor and the second capacitor, the inductance of each of the first inductor and the third inductor may be 0.8 times to 1.2 times Zo/(2πfo), and the inductance of each of the second inductor and the fourth inductor may be 0.8 times to 1.2 times Zo/(√2×(2πfo)). Thus, the amplifying circuit can function as the balanced amplifier.

(7) The amplifying circuit according to any one of the above (1) to (6) may include a first semiconductor chip including the first amplifier and a first pad corresponding to the first node, and a second semiconductor chip including the second amplifier and a second pad corresponding to the second node. The first inductor may include a first bonding wire having a first end connected to the first pad. This can reduce the deterioration of the characteristics.

(8) In the above (7), the first bonding wire may have a second end connected to the second pad. This can reduce the deterioration of the characteristics.

(9) In the above (7), the first inductor may include a second bonding wire having a first end connected to the second pad. This can reduce the deterioration of the characteristics.

(10) The amplifying circuit according to any one of the above (7) to (9) may include a third bonding wire connecting the first pad to the first capacitor, the third bonding wire corresponding to the second inductor, and a fourth bonding wire connecting the second pad to the second capacitor, the fourth bonding wire corresponding to the fourth inductor. Thus, the second inductor and the fourth inductor can be formed.

(11) In any one of the above (7) to (10), the first inductor, the second inductor, the third inductor, the fourth inductor, the first capacitor, the second capacitor, a first ground capacitance of the first pad, and a second ground capacitance of the second pad may form a branch-line coupler. This can reduce deterioration of characteristics of the branch-line coupler.

(12) The amplifying circuit according to any one of the above (1) to (11) may include another divider that divides a high frequency signal into the input signal and a fifth signal, and a control amplifier that amplifies the fifth signal and outputs the amplified fifth signal as a sixth signal. A combiner including the first inductor, the second inductor, the third inductor, the fourth inductor, the first capacitor, and the second capacitor may be configured to modulate a load of the first amplifier and the second amplifier by using the sixth signal, combine the third signal, the fourth signal, and the sixth signal into a combined signal, and output the combined signal as an output signal. This can reduce the deterioration of the characteristics.

### [Details of Embodiments of Present Disclosure]

Specific examples of an amplifying circuit according to embodiments of the present disclosure will be described below with reference to the drawings. It should be noted that the present disclosure is not limited to these examples, but is defined by the claims and is intended to include all modifications within the meaning and scope equivalent to the claims.

### First Embodiment

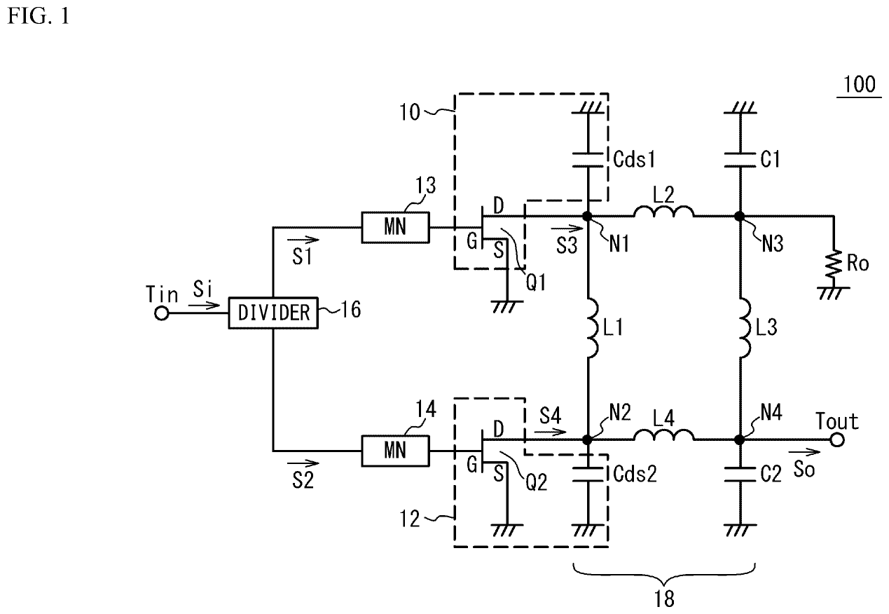

A first embodiment is an example of a balanced amplifier. FIG. 1 is a circuit diagram of an amplifying circuit according to the first embodiment. In FIG. 1, bias circuits for supplying bias voltages to amplifiers 10 and 12 are not illustrated.

As illustrated in FIG. 1, in an amplifying circuit 100 of the first embodiment, amplifiers 10 and 12 are connected in parallel between an input terminal Tin and an output terminal Tout. A high frequency signal is received at input terminal Tin as an input signal Si. When amplifying circuit 100 is used in a base station of mobile communication, the frequency of the high frequency signal is, for example, 0.5 GHz to 10 GHz. A divider 16 divides input signal Si received at input terminal Tin into signals S1 (first signal) and S2 (second signal). A phase of signal S2 is delayed by 90 degrees with respect to a phase of signal S1.

Signal S1 passes through a matching circuit (MN: Matching Network) 13 and is received at amplifier 10. In all figures, matching circuit is illustrated as “MN”. Matching circuit 13 matches an impedance when matching circuit 13 is viewed from divider 16 with an impedance when amplifier 10 is viewed from matching circuit 13. Amplifier 10 (first amplifier) amplifies signal S1 and outputs amplified signal S1 as a signal S3 (third signal). Signal S3 amplified by amplifier 10 is received at a node N1.

Signal S2 passes through a matching circuit 14 and is received at amplifier 12. Matching circuit 14 matches an impedance when matching circuit 14 is viewed from divider 16 with an impedance when amplifier 12 is viewed from matching circuit 14. Amplifier 12 (second amplifier) amplifies signal S2 and outputs amplified signal S2 as a signal S4 (fourth signal). Signal S4 amplified by amplifier 12 is received at a node N2.

Amplifiers 10 and 12 include transistors Q1 and Q2 such as Field Effect Transistors (FET), respectively. In each of transistors Q1 and Q2, a source S is grounded, a high frequency signal is received at a gate G, and a high frequency signal is output from a drain D. Transistors Q1 and Q2 are, for example, Gallium Nitride High Electron Mobility Transistors (GaN HEMT) or Laterally Diffused Metal Oxide Semiconductors (LDMOS). Parasitic capacitance Cds1 is present between the drain D and the source S of transistors Q1 and parasitic capacitance Cds2 is present between the drain D and the source S of transistor Q2.

A combiner 18 is a lumped-constant type branch-line coupler, and includes parasitic capacitances Cds1 and Cds2, capacitors C1 and C2, and inductors L1 to L4. Inductor L1 (first inductor) electrically connects node N1 (first node) and node N2 (second node) to each other. Inductor L2 (second inductor) electrically connects node N1 and a node N3 (third node) to each other. Inductor L3 (third inductor) electrically connects node N3 and a node N4 (fourth node) to each other. Inductor L4 (fourth inductor) electrically connects nodes N2 and node N4 to each other. Capacitor C1 (first capacitor) is shunt-connected to node N3. Capacitor C2 (second capacitor) is shunt-connected to node N4. Node N3 is grounded via a reference resistor Ro (for example, 50Ω). Node N4 is electrically connected to output terminal Tout. Signals S3 and S4 are combined at node N4, and the combined signal is output from output terminal Tout as an output signal So.

When amplifying circuit 100 is a balanced amplifier, divider 16 divides input signal Si into signals S1 and S2 so that amplitudes of signals S1 and S2 are substantially the same as each other, and a phase of signal S2 at a center frequency fo of an operating band is delayed from a phase of signal S1 by substantially 90 degrees. Combiner 18 delays a phase of signal S3 by 90 degrees and combines signal S3 with signal S4. Note that 90 degrees do not have to be exactly 90 degrees, and may be, for example, 3λ/16 to 5λ/16, or 7λ/32 to 9λ/32, in terms of the wavelength λ at the center frequency fo of the operating band. The same applies to the following embodiments. Amplifying circuit 100 may be an amplifying circuit other than the balanced amplifier.

### [Combiner 18]

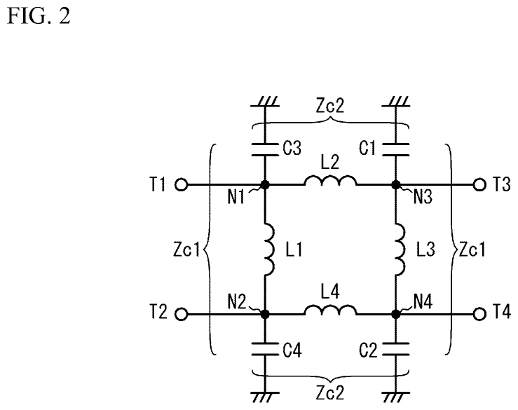

First, the lumped-constant type branch-line coupler will be described. FIG. 2 is a circuit diagram of the lumped-constant type branch-line coupler. As illustrated in FIG. 2, capacitors C3 and C4 are provided in place of parasitic capacitances Cds1 and Cds2 of combiner 18 of FIG. 1, respectively. Nodes N1 to N4 are electrically connected to terminals T1 to T4, respectively. A method of determining values of capacitors C1 to C4 and inductors L1 to L4 of the lumped-constant type branch-line coupler will be described.

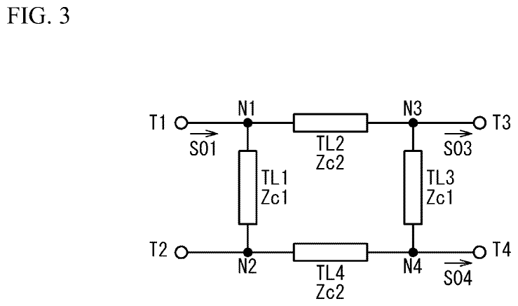

In order to explain how to determine the values of capacitors C1 to C4 and inductors L1 to L4 of the lumped-constant type branch-line coupler, a distributed-constant type branch-line coupler will be described. FIG. 3 is a circuit diagram of the distributed-constant type branch-line coupler. As illustrated in FIG. 3, transmission lines TL1, TL2, TL3 and TL4 are connected between nodes N1 and N2, between nodes N1 and N3, between nodes N3 and N4, and between nodes N2 and N4, respectively. A length of each of transmission lines TL1 to TL4 is N4. A characteristic impedance of each of transmission lines TL1 and TL3 is Zc1, and a characteristic impedance of each of transmission lines TL2 and TL4 is Zc2. It is assumed that a signal S01 is received at terminal T1 and is output from terminals T3 and T4 as signals S03 and S04. At this time, the ratio of the amplitude of signal S03 to the amplitude of signal S04 is expressed as S03-S04 in dB.

Table 1 illustrates characteristic impedances Zc1 and Zc2 for achieving the ratio S03-S04.

TABLE 1

| S03-S04[dB] | −5 | −3 | −2 | 0 | 2 | 3 | 5 |
|---|---|---|---|---|---|---|---|
| Zc1 [Ω] | 28.10 | 35.40 | 39.70 | 50 | 63.00 | 70.60 | 89.00 |
| Zc2 [Ω] | 24.49 | 28.89 | 31.09 | 35.35 | 39.16 | 40.80 | 43.59 |
| \sqrt{2} · Zc2/Zc1 | 1.233 | 1.154 | 1.108 | 1.000 | 0.879 | 0.817 | 0.693 |

In Table 1, a reference impedance Zo is set to 50Ω. Reference impedance Zo corresponds to an impedance of each of terminals T1, T2, T3 and T4 when viewed from the outside. In particular, in FIG. 1, reference impedance Zo is an impedance when node N4 is viewed from output terminal Tout to which a load is connected, and corresponds to a characteristic impedance of a transmission line connecting node N2 and output terminal Tout.

In Table 1, the values of capacitors C1 to C4 and inductors L1 to L4 in the lumped-constant type branch-line coupler that provides the desired S03-S04 will be described. A capacitance of each of capacitors C1 to C4 is denoted by C0, an inductance of each of inductors L1 and L3 is denoted by L01, and an inductance of each of inductors L2 and L4 is denoted by L02. A center frequency of an operating band is denoted by fo. In this case, capacitance C0, inductance L01, and inductance L02 are determined by the following formulas.

$$C 0 = 1 / ( 2 π fo \times Zc 1 ) + 1 / ( 2 π fo \times Zc 2 ) \qquad ( formula 1 )$$

$$L 01 = Zc 1 / ( 2 π fo ) \qquad ( formula 2 )$$

$$L 02 = Zc 2 / ( 2 π fo ) \qquad ( formula 3 )$$

In FIG. 1, when parasitic capacitances Cds1 and Cds2 satisfy formula 1, by setting the inductances of inductors L1 to L4 and the capacitances of capacitors C1 and C2 in FIG. 1 so as to satisfy formulas 1 to 3, combiner 18 including parasitic capacitances Cds1 and Cds2 in FIG. 1 functions as the lumped-constant type branch-line coupler. The inductances of inductors L1 to L4 and the capacitances of capacitors C1 and C2 do not have to be strictly the values calculated by the formulas 1 to 3. For example, the capacitance C0 which corresponds to each capacitance of parasitic capacitances Cds1 and Cds2 and capacitors C1 and C2 may be 0.8 times to 1.2 times, or 0.9 times to 1.1 times the value obtained from formula 1. Inductance L01 of each of inductors L1 and L3 may be 0.8 times to 1.2 times, or 0.9 times to 1.1 times the value obtained by formula 2. Inductance L02 of each of inductors L2 and L4 may be 0.8 times to 1.2 times, or 0.9 times to 1.1 times the value obtained by formula 3.

### First Comparative Example

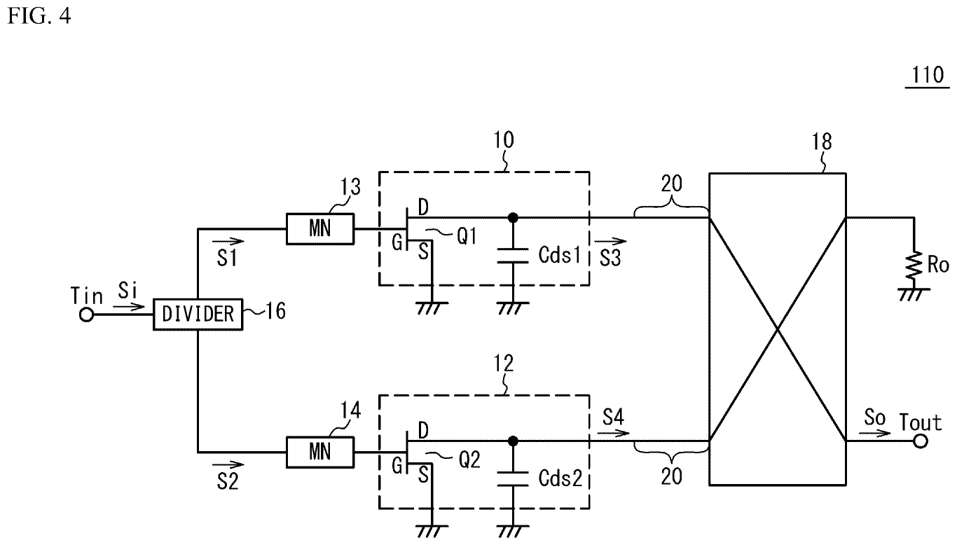

FIG. 4 is a circuit diagram of an amplifying circuit according to a first comparative example. As illustrated in FIG. 4, in an amplifying circuit 110 of the first comparative example, combiner 18 is provided separately from parasitic capacitances Cds1 and Cds2 of amplifiers 10 and 12. Combiner 18 is the branch-line coupler of the distributed-constant type or the lumped-constant type. The other configurations are the same as those of the first embodiment.

In first comparative example, lines 20 such as bonding wires or transmission lines are provided between amplifier 10 and combiner 18, and between amplifier 12 and combiner 18. An insertion loss is increased by lines 20. Further, ground parasitic capacitances Cds1 and Cds2 are added to outputs of amplifiers 10 and 12. Thus, it is difficult to widen the band of amplifying circuit 110.

According to the first embodiment, in FIG. 1, inductance L01 of each of inductors L1 and L3 are larger than inductance L02 of each of inductors L2 and L4. Thus, as illustrated in Table 1, combiner 18 functions as the lumped-constant type branch-line coupler. Line 20 in the first comparative example is at least a part of inductor L2 or L4 in combiner 18. Thus, a loss due to lines 20 can be reduced. Further, parasitic capacitances Cds1 and Cds2 function as capacitors C3 and C4 of the lumped-constant type branch-line coupler illustrated in FIG. 2. This can widen the band. As described above, the deterioration of the characteristics can be reduced.

As illustrated in Table 1, when S03-S04 is 0 dB, Zc2 is approximately Zc1/√2. Thus, inductance L01 may be 0.8×√2 to 1.2×√2 of inductance L02. Thus, combiner 18 functions as the branch-line coupler.

No reactance element such as a capacitor or an inductor is shunt-connected to nodes N1 and N2. Thus, parasitic capacitances Cds1 and Cds2 function as capacitors C3 and C4 in FIG. 2, respectively. Thus, combiner 18 functions as the branch-line coupler.

When amplifying circuit 100 is the balanced amplifier, S03-S04 is 0 dB in Table 1. In this case, Zc1 is Zo and Zc2 is Zc/√2. Thus, in Formula 1 to Formula 3, when parasitic capacitance Cds1 (the first ground capacitance of the output node of amplifier 10), parasitic capacitance Cds2 (the second ground capacitance of the output node of amplifier 12), and the capacitances of capacitors C1 and C2 are C0, C0 may be 0.8 times to 1.2 times 1/(2πfo× Zo)+1/(2πfo×Zo/√2), and may be 0.9 times to 1.1 times 1/(2πfo× Zo)+1/(2πfo×Zo/√2). Inductance L01 of each of inductors L1 and L3 may be 0.8 times to 1.2 times Zo/(2πfo), and may be 0.9 times to 1.1 times Zo/(2πfo). Inductance L02 of each of inductors L2 and L4 may be 0.8 times to 1.2 times Zo/(√2×(2πfo)), and may be 0.9 times to 1.1 times Zo/(√2×(2πfo)).

When amplifying circuit 100 is the balanced amplifier, saturation power of amplifier 10 is substantially the same as that of amplifier 12. For example, a difference in the saturation power between amplifiers 10 and 12 is 1 dB or less or 2 dB or less.

### [First Implementation Example of First Embodiment]

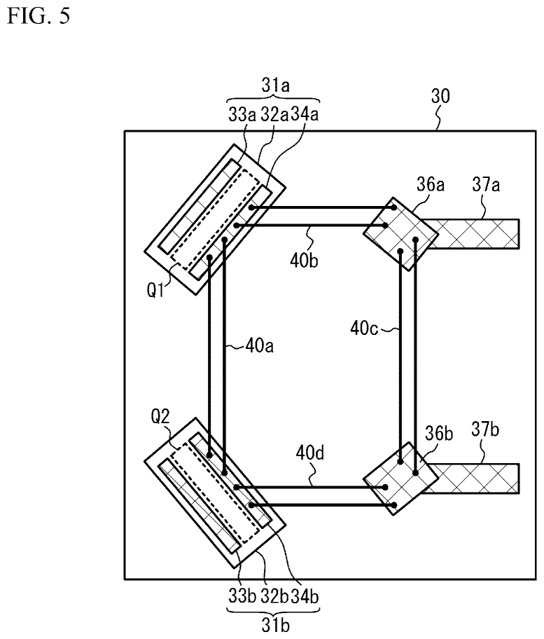

FIG. 5 is a plan view illustrating a first implementation example of the combiner and the amplifier in the first embodiment. As illustrated in FIG. 5, semiconductor chips 31a and 31b, Metal Insulator Metal (MIM) capacitors 36a and 36b, lines 37a and 37b are mounted on a substrate 30. An upper surface of substrate 30 is, for example, a conductor layer, and a reference potential, such as a ground potential, is supplied thereto. Semiconductor chip 31a includes transistor Q1 corresponding to amplifier 10, a substrate 32a, and pads 33a and 34a provided on substrate 32a. Semiconductor chip 31b includes transistor Q2 corresponding to amplifier 12, a substrate 32b, and pads 33b and 34b provided on substrate 32b. Pads 33a and 33b are input pads for receiving high frequency signals, and are, for example, gate pads. Pads 34a and 34b are output pads for outputting high frequency signals, and are, for example, drain pads. When transistors Q1 and Q2 are GaN HEMTs, substrates 32a and 32b are, for example, silicon carbide substrates, sapphire substrates, or gallium nitride substrates. Pads 33a, 33b, 34a, and 34b are, for example, gold layers, copper layers, or aluminum layers.

Each of MIM capacitors 36a and 36b includes a lower electrode, an upper electrode, and a dielectric layer sandwiched between the lower electrode and the upper electrode. The lower electrode is electrically connected to the conductor layer to which the reference potential of the upper surface of substrate 30 is supplied. Lines 37a and 37b are electrically connected to the upper electrodes of MIM capacitors 36a and 36b, respectively. A dielectric layer is provided between the conductor layer to which the reference potential is supplied and lines 37a and 37b. Lines 37a and 37b are transmission lines, such as microstrip lines. A characteristic impedance of each of the transmission lines formed with lines 37a and 37b at the center frequency fo is approximately equal to the reference impedance.

Pads 34a and 34b are electrically connected to each other by bonding wires 40a. Pad 34a and the upper electrode of MIM capacitor 36a are electrically connected to each other by bonding wires 40b. The upper electrode of MIM capacitor 36a and the upper electrode of MIM capacitor 36b are electrically connected by bonding wires 40c. Pad 34b and the upper electrode of MIM capacitor 36b are electrically connected to each other by bonding wires 40d.

Semiconductor chips 31a and 31b correspond to amplifiers 10 and 12 of FIG. 1, respectively. MIM capacitors 36a and 36b correspond to capacitors C1 and C2 of FIG. 1, respectively. Bonding wires 40a, 40b, 40c and 40d correspond to inductors L1, L2, L3 and L4 of FIG. 1, respectively.

### [Second Implementation Example of First Embodiment]

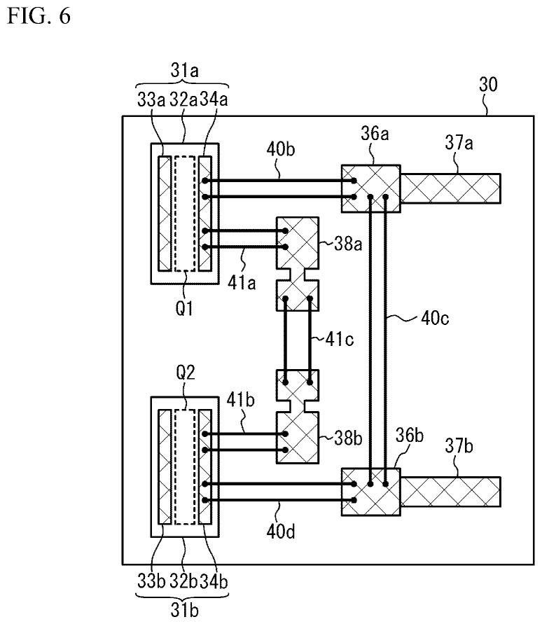

FIG. 6 is a plan view illustrating a second implementation example of the combiner and the amplifier in the first embodiment. As illustrated in FIG. 6, conductive patterns 38a and 38b are provided on substrate 30. Bonding wires 41a electrically connect pad 34a to pattern 38a. Bonding wires 41b electrically connect pad 34b to pattern 38b. Bonding wires 41c electrically connect pattern 38a to pattern 38b. Bonding wires 41a to 41c and patterns 38a and 38b form inductor L1. The other configurations are the same as that of the first implementation example of FIG. 5, and the description thereof is omitted.

In the first and second implementation examples of the first embodiment, semiconductor chip 31a (first semiconductor chip) includes amplifier 10 and pad 34a (first pad) corresponding to node N1. Semiconductor chip 31b (second semiconductor chip) includes amplifier 12 and pad 34b (second pad) corresponding to node N2. Inductor L1 includes bonding wire 40a or 41a (first bonding wire) having a first end connected to pad 34a. Thus, pad 34a can function as node N1. Thus, it is possible to reduce the provision of extra lines such as lines 20 as in the first comparative example, and to reduce the deterioration of the characteristics.

As in the first implementation example of the first embodiment, a second end of each of bonding wires 40a is connected to pad 34b. Thus, pad 34b can function as node N2. Thus, it is possible to reduce the provision of extra lines such as lines 20 as in the first comparative example, and to reduce the deterioration of the characteristics.

As in the second implementation example of the first embodiment, inductor L1 includes bonding wires 41b (second bonding wire) each having a first end connected to pad 34b. Thus, pad 34b can function as node N2. Thus, it is possible to reduce the provision of extra lines such as lines 20 as in the first comparative example, and to reduce the deterioration of the characteristics.

Each of bonding wires 40b (third bonding wire) connects pad 34a to capacitor C1r, and corresponds to inductor L2. Each of bonding wires 40d (fourth bonding wire) connects pad 34b to capacitor C2, and corresponds to inductor L4. Thus, bonding wires 40b and 40d can form inductors L2 and L4, respectively.

### Second Embodiment

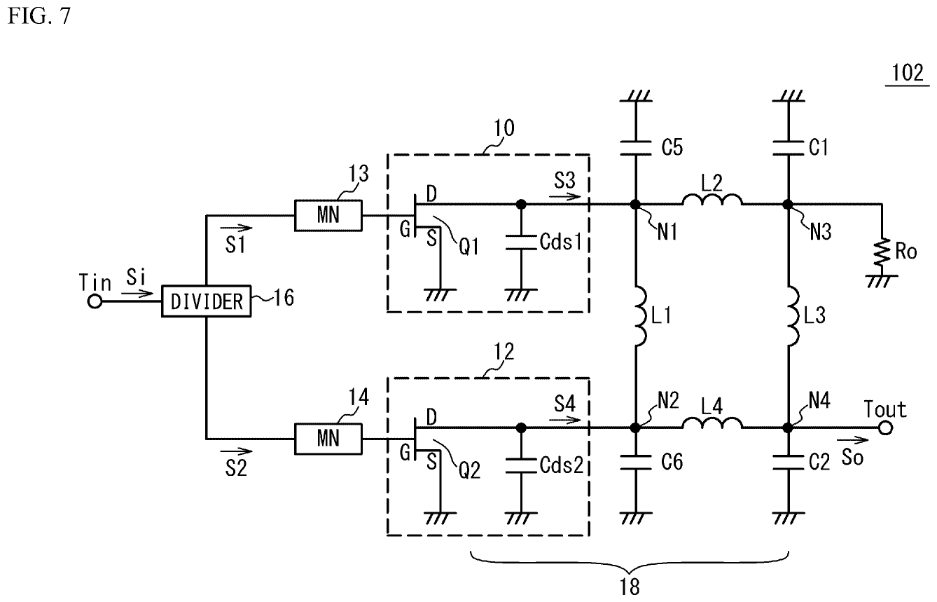

FIG. 7 is a circuit diagram of an amplifying circuit according to a second embodiment. As illustrated in FIG. 7, in an amplifying circuit 102 of the second embodiment, a capacitor C5 is shunt-connected to node N1, and a capacitor C6 is shunt-connected to node N2. The other configurations are the same as those of the first embodiment, and the description thereof is omitted.

When parasitic capacitances Cds1 and Cds2 are smaller than C0 calculated from Table 1, capacitors C5 and C6 are provided, whereby the capacitances of capacitor C3 and C4 in FIG. 2 can be set to desired values. In this case, the capacitances of capacitors C5 and C6 are smaller than the capacitances of capacitors C1 and C2.

### [Implementation Example of Second Embodiment]

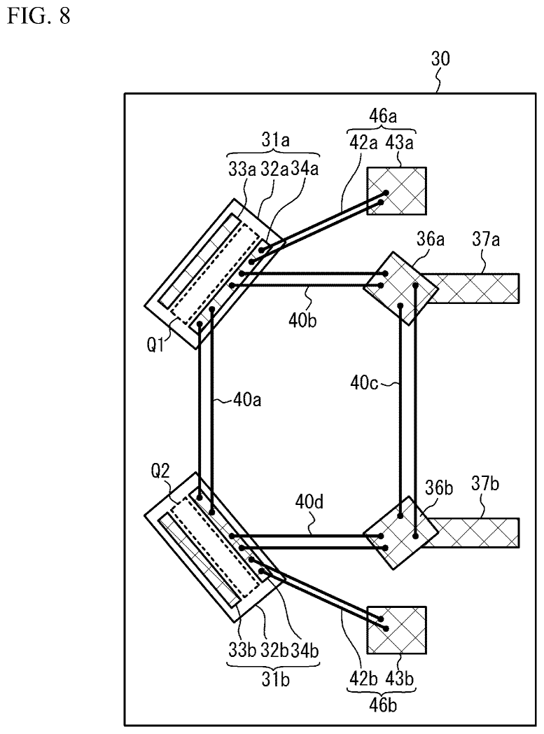

FIG. 8 is a plan view illustrating an implementation example of the combiner and the amplifier in the second embodiment. As illustrated in FIG. 8, MIM capacitors 43a and 43b are provided on substrate 30. The structures of MIM capacitors 43a and 43b are the same as those of MIM capacitors 36a and 36b. Each of bonding wires 42a electrically connects pad 34a to an upper electrode of MIM capacitor 43a. Each of bonding wires 42b electrically connects pad 34b to an upper electrode of MIM capacitor 43b. Lower electrodes of MIM capacitors 43a and 43b are electrically connected to the conductor layer to which the reference potential is supplied. The other configurations are the same as that of the first implementation example of FIG. 5, and the description thereof is omitted.

MIM capacitors 43a and 43b correspond to capacitors C5 and C6 of FIG. 7, respectively. Bonding wire 42a and MIM capacitor 43a form a conductive reactance element 46a. Bonding wire 42b and MIM capacitor 43b form a conductive reactance element 46b.

### Third Embodiment

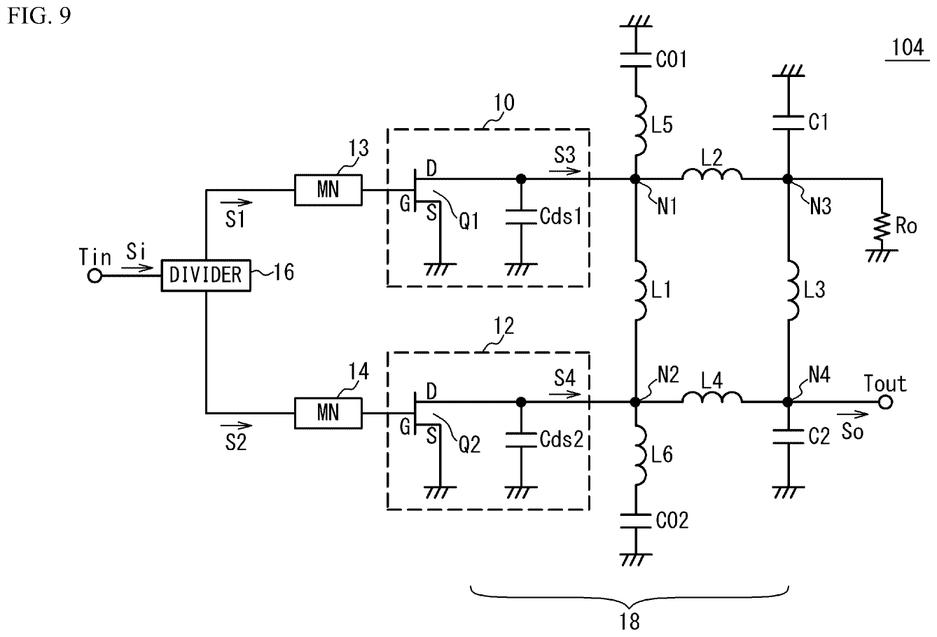

FIG. 9 is a circuit diagram of an amplifying circuit according to a third embodiment. As illustrated in FIG. 9, in an amplifying circuit 104 of the third embodiment, an inductor L5 is shunt-connected to node N1, and an inductor L6 is shunt-connected to node N2. A capacitor C01 is electrically connected between inductor L5 and the ground, and a capacitor C02 is electrically connected between inductor L6 and the ground. Capacitors C01 and C02 are bias voltage cutting capacitors for reducing the bias currents from flowing to the ground. The other configurations are the same as those of the second embodiment, and the description thereof is omitted.

When parasitic capacitances Cds1 and Cds2 are larger than C0 calculated from Table 1, inductors L5 and L6 are provided, whereby the capacitances of capacitor C3 and C4 in FIG. 2 can be set to desired values.

### [Implementation Example of Third Embodiment]

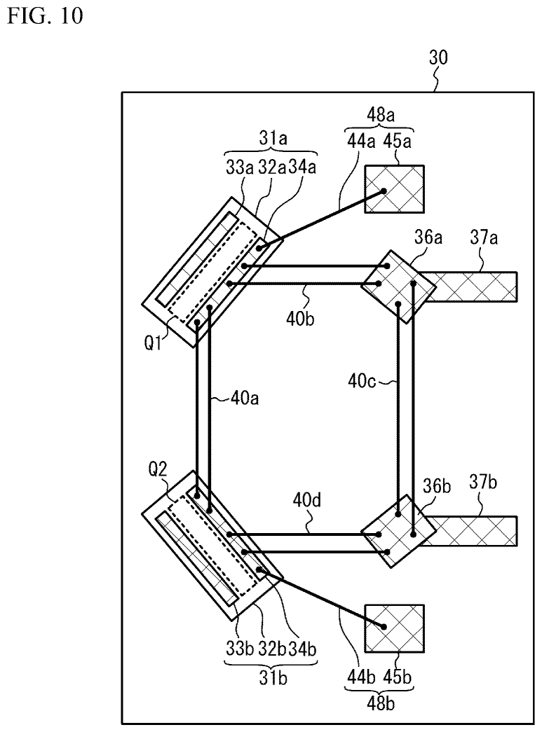

FIG. 10 is a plan view illustrating an implementation example of the combiner and the amplifier in third embodiment. As illustrated in FIG. 10, MIM capacitors 45a and 45b are provided on substrate 30. The structures of MIM capacitors 45a and 45b are the same as those of MIM capacitors 36a and 36b. MIM capacitors 45a and 45b are capacitors C01 and C02, respectively. A bonding wire 44a electrically connects pad 34a to an upper electrode of MIM capacitor 45a. A bonding wire 44b electrically connects pad 34b to an upper electrode of MIM capacitor 45b. Lower electrodes of MIM capacitors 45a and 45b are electrically connected to the conductor layer to which the reference potential is supplied. The other configurations are the same as that of the implementation example of the second embodiment in FIG. 8, and the description thereof is omitted.

Bonding wires 44a and 44b correspond to inductors L5 and L6 in FIG. 9, respectively. Bonding wire 44a and MIM capacitor 45a form an inductive reactance element 48a. Bonding wire 44b and MIM capacitor 45b form an inductive reactance element 48b.

According to the second and third embodiments, reactance element 46a or 48a (first reactance element) is shunt-connected to node N1. Reactance element 46b or 48b (second reactance element) is shunt-connected to node N2. Thus, even when parasitic capacitances Cds1 and Cds2 are different from capacitance C0 calculated from Table 1, the capacitances of capacitors C3 and C4 in FIG. 2 can be made closer to C0. Thus, combiner 18 functions as the branch-line coupler.

Capacitance C0 may be 0.8 times to 1.2 times 1/(2πfo×Zo)+1/(2πfo×Zo/√2), or 0.9 times to 1.1 times 1/(2πfo×Zo)+1/(2πfo×Zo/√2), where capacitance C0 represents a capacitance component obtained by combining parasitic capacitance Cds1 and reactance element 46a or 48a, a capacitance component obtained by combining parasitic capacitance Cds2 and reactance element 46b or 48b, and the capacitance of each of capacitors C1 and C2. Inductance L01 of each of inductors L1 and L3 may be 0.8 times to 1.2 times Zo/(2πfo), and may be 0.9 times to 1.1 times Zo/(2πfo). Inductance L02 of each of inductors L2 and L4 may be 0.8 times to 1.2 times Zo/(√2×(2πfo)), and may be 0.9 times to 1.1 times Zo/(√2×(2πfo)). Thus, amplifying circuits 102 and 104 can be used as the balanced amplifiers.

### Fourth Embodiment

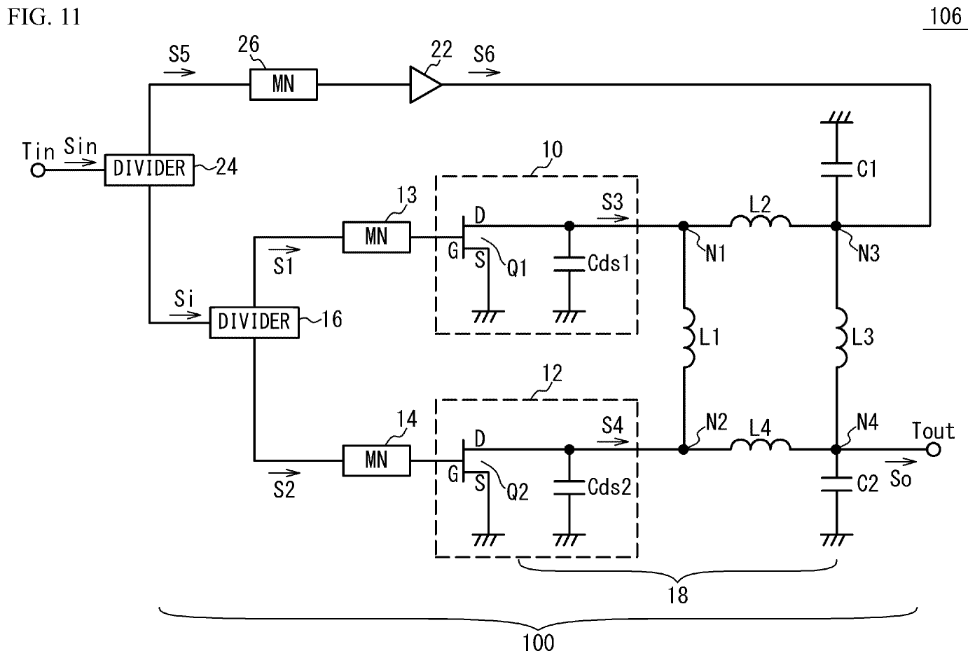

A fourth embodiment is an example of a Load Modulated Balanced Amplifier (LMBA). FIG. 11 is a circuit diagram of an amplifying circuit according to the fourth embodiment. As illustrated in FIG. 11, in an amplifying circuit 106 of the fourth embodiment, a control amplifier 22 and amplifiers 10 and 12 are connected in parallel between input terminal Tin and output terminal Tout. A high frequency signal is received at input terminal Tin as an input signal Sin. A divider 24 (another divider) divides input signal Sin received at input terminal Tin into a signal S5 (fifth signal) and input signal Si.

Signal S5 is received at control amplifier 22 via a matching circuit 26. Matching circuit 26 matches an impedance when matching circuit 26 is viewed from divider 24 with an impedance when control amplifier 22 is viewed from matching circuit 26. Control amplifier 22 amplifies signal S5 and outputs the amplified signal as a signal S6 (sixth signal). Signal S6 amplified by control amplifier 22 is output to node N3 of combiner 18.

Input signal Si divided by divider 24 is received at amplifying circuit 100. Amplifying circuit 100 is the same as amplifying circuit 100 of the first embodiment except that signal S6 is received at node N3 of combiner 18, and thus the description thereof will be omitted.

Control amplifier 22 corresponds to a main amplifier of the Doherty amplifier circuit, and amplifiers 10 and 12 correspond to peak amplifiers of the Doherty amplifier circuit. Control amplifier 22 operates in class AB or class B, and amplifiers 10 and 12 operate in class C. When the input power of input signal Sin is small, control amplifier 22 mainly amplifies input signal Sin. When the input power increases, amplifiers 10 and 12 amplify the peak of input signal Sin in addition to control amplifier 22. Thus, control amplifier 22 and amplifiers 10 and 12 amplify input signal Sin.

Combiner 18 modulates loads of amplifiers 10 and 12 by using signal S6, combines signals S3, S4, and S6, and outputs a combined signal as output signal So. This will be described in detail below.

When the power of input signal Si is small and amplifiers 10 or 12 are not operating, signal S6 received at node N3 of combiner 18 is divided into two signals S6/2 toward nodes N1 and N2. The phase of signal S6/2 of node N2 is delayed from the phase of signal S6/2 of node N1 by 90 degrees. Signals S6/2 are reflected at nodes N1 and N2. Signals S6/2 are combined in node N4. The phase of signal S6/2 reflected at node N1 is delayed from the phase of signal S6/2 reflected at node N2 by 90 degrees. Thus, the phases of two signals S6/2 are aligned at node N4, and signal S6 is combined. The combined signal S6 is output to output terminal Tout as output signal So. At this time, a reflection coefficient when combiner 18 is viewed from amplifiers 10 and 12 is approximately 1, and load impedances of amplifiers 10 and 12 are substantially high.

When the power of input signal Sin is large and amplifiers 10 and 12 are operating, signal S4 has a phase delayed from a phase of signal S3 by 90 degrees. Signal S6/2 at node N2 has a phase delayed from a phase of signal S6/2 at node N1 by 90 degrees. Signal S3+S6/2 combined at node N1 and signal S4+S6/2 combined at node N2 are combined at node N4. The combined signal S3+S4+S6 is output to output terminal Tout as output signal So. At this time, the reflection coefficient when combiner 18 is viewed from amplifiers 10 and 12 is smaller than 1, and the reflection coefficient decreases as the amplitudes of signals S3 and S4 increase. Thus, the load impedances of amplifiers 10 and 12 are substantially reduced. As described above, combiner 18 modulates the load impedances when combiner 18 is viewed from amplifiers 10 and 12 depending on the amplitudes of signals S3 and S4.

In the Doherty amplifier circuit, a combiner that combines a signal amplified by the main amplifier and a signal amplified by the peak amplifier includes a λ/4 line as an impedance converter. The load impedance of the main amplifier is modulated using the λ/4 line. In this case, when the frequency changes, the electrical length of the N/4 line deviates from 24, and thus it is difficult to widen the operating band. For example, the fractional bandwidth of a combiner using a 24 line is about 8%.

In the LMBA as in the fourth embodiment, combiner 18 modulates the loads of amplifiers 10 and 12 by using signal S6, combines signals S3, S4, and S6, and outputs a combined signal as output signal So. This can widen the band of the operating band. For example, the fractional bandwidth of a 90 degrees coupler is 120% at the maximum in, for example, a commercially available 90 degrees hybrid coupler.

By using any one of the amplifying circuits of the first to third embodiments for the LMBA, it is possible to reduce the deterioration of the characteristics of amplifying circuit 106. The high frequency characteristics can be improved. In particular, when the loss due to line 20 is large as in the first comparative example, the reflection coefficients of signals S6/2 at nodes N1 and N2 is smaller than 1. This increases the loss in combiner 18. In the fourth embodiment, since no extra line such as the line 20 is provided, the loss in the combiner 18 can be reduced. In LMBA or the like, S03-S04 in Table 1 may be negative or positive other than 0 dB.

The embodiments disclosed here should be considered illustrative in all respects and not restrictive. The present disclosure is not limited to the specific embodiments described above, but various variations and changes are possible within the scope of the gist of the present disclosure as described in the claims.

What is claimed is:

1. An amplifying circuit comprising:
a divider that divides an input signal into a first signal and a second signal having a phase delayed from a phase of the first signal by 90 degrees;
a first amplifier that amplifies the first signal and outputs the amplified first signal to a first node as a third signal;
a second amplifier that amplifies the second signal and outputs the amplified second signal to a second node as a fourth signal;
a first inductor that connects the first node to the second node;
a second inductor that connects the first node to a third node;
a third inductor that connects the third node to a fourth node, the fourth node outputting an output signal obtained by combining the fourth signal and the third signal, the third signal having a phase delayed from a phase of the fourth signal by 90 degrees;
a fourth inductor that connects the second node to the fourth node;
a first capacitor shunt-connected to the third node; and
a second capacitor shunt-connected to the fourth node, wherein
an inductance of each of the first inductor and the third inductor is larger than an inductance of each of the second inductor and the fourth inductor.

2. The amplifying circuit according to claim 1, wherein
the inductance of each of the first inductor and the third inductor is 0.8×√2 to 1.2×√2 of the inductance of each of the second inductor and the fourth inductor.

3. The amplifying circuit according to claim 1, wherein
no reactance element is shunt-connected to each of the first node and the second node.

4. The amplifying circuit according to claim 3, wherein
when a center frequency of an operating band is denoted by fo, and a reference impedance is denoted by Zo,
a capacitance C0 is 0.8 times to 1.2 times 1/(2πfo×Zo)+1/(2πfo×Zo/√2), the capacitance C0 being a first ground capacitance of an output node of the first amplifier, a second ground capacitance of an output node of the second amplifier, and capacitances of the first capacitor and the second capacitor,
the inductance of each of the first inductor and the third inductor is 0.8 times to 1.2 times Zo/(2πfo), and
the inductance of each of the second inductor and the fourth inductor is 0.8 times to 1.2 times Zo/(√2×(2πfo)).

5. The amplifying circuit according to claim 1, further comprising:
a first reactance element shunt-connected to the first node; and
a second reactance element shunt-connected to the second node.

6. The amplifying circuit according to claim 5, wherein
when a center frequency of an operating band is denoted by fo, and a reference impedance is denoted by Zo,
a capacitance C0 is 0.8 times to 1.2 times 1/(2πfo×Zo)+1/(2πfo×Zo/√2), the capacitance C0 being a capacitance component obtained by combining a first ground capacitance of an output node of the first amplifier and the first reactance element, a capacitance component obtained by combining a second ground capacitance of an output node of the second amplifier and the second reactance element, and a capacitance of the first capacitor and the second capacitor,
the inductance of each of the first inductor and the third inductor is 0.8 times to 1.2 times Zo/(2πfo), and
the inductance of each of the second inductor and the fourth inductor is 0.8 times to 1.2 times Zo/(√2×(2πfo)).

7. The amplifying circuit according to claim 1, further comprising:
a first semiconductor chip including the first amplifier and a first pad corresponding to the first node; and
a second semiconductor chip including the second amplifier and a second pad corresponding to the second node, wherein
the first inductor includes a first bonding wire having a first end connected to the first pad.

8. The amplifying circuit according to claim 7, wherein
the first bonding wire has a second end connected to the second pad.

9. The amplifying circuit according to claim 7, wherein
the first inductor includes a second bonding wire having a first end connected to the second pad.

10. The amplifying circuit according to claim 7, further comprising:
a third bonding wire connecting the first pad to the first capacitor, the third bonding wire corresponding to the second inductor; and
a fourth bonding wire connecting the second pad to the second capacitor, the fourth bonding wire corresponding to the fourth inductor.

11. The amplifying circuit according to claim 7, wherein
the first inductor, the second inductor, the third inductor, the fourth inductor, the first capacitor, the second capacitor, a first ground capacitance of the first pad, and a second ground capacitance of the second pad form a branch-line coupler.

12. The amplifying circuit according to claim 1, further comprising:
another divider that divides a high frequency signal into the input signal and a fifth signal; and
a control amplifier that amplifies the fifth signal and outputs the amplified fifth signal as a sixth signal, wherein
a combiner including the first inductor, the second inductor, the third inductor, the fourth inductor, the first capacitor, and the second capacitor is configured to modulate a load of the first amplifier and the second amplifier by using the sixth signal, combine the third signal, the fourth signal, and the sixth signal into a combined signal, and output the combined signal as an output signal.
